(19) United States
(12) Patent Application Publication
(10) Pub. No.: US 2022/0123244 A1
(43) Pub. Date: Apr. 21, 2022

(54) TRANSPARENT ELECTRODE STRUCTURE AND ELECTRICAL DEVICE INCLUDING THE SAME

(71) Applicant: DONGWOO FINE-CHEM CO., LTD., Jeollabuk-do (KR)

(72) Inventors: Han Tae RYU, Gyeonggi-do (KR); Dong Ki KEUM, Seoul (KR); Myeong Won LEE, Seoul (KR)

(21) Appl. No.: 17/567,518

(22) Filed: Jan. 3, 2022

Related U.S. Application Data
(63) Continuation of application No. PCT/KR2020/008755, filed on Jul. 3, 2020.

(30) Foreign Application Priority Data
Jul. 5, 2019 (KR) 10-2019-0081070
Jul. 3, 2020 (KR) 10-2020-0081937

(51) Int. Cl. H01L 51/44; H01L 51/52

(52) U.S. Cl. CPC H01L 51/442; H01L 2251/305; H01L 51/5206

(57) ABSTRACT

A transparent electrode structure according to an embodiment of the present invention includes a transparent substrate, a transparent electrode layer disposed on the transparent substrate and including a multi-layered structure of a transparent oxide electrode layer and a metal layer, and a barrier structure disposed between the transparent substrate and the transparent electrode layer and including at least one barrier material of an aluminum oxide-zinc oxide composite (AlZO) material, silazane, siloxane or a silicon-containing inorganic material. Electrical, optical and chemical stability may be improved by a combination of the transparent electrode layer and the barrier structure.

### CROSS-REFERENCE TO RELATED APPLICATION AND CLAIM OF PRIORITY

The present application is a continuation application to International Application No. PCT/KR2020/008755 with an International Filing Date of Jul. 3, 2020, which claims the benefit of Korean Patent Applications No. 10-2019-0081070 filed on Jul. 5, 2019 and No. 10-2020-0081937 filed on Jul. 3, 2020 at the Korean Intellectual Property Office, the disclosures of which are incorporated by reference herein in their entirety.

### BACKGROUND

### 1. Field

The present invention relates to a transparent electrode structure and an electrical device including the same. More particularly, the present invention relates to a transparent electrode structure including an insulation layer and an electrode layer, and an electrical device including the same.

### 2. Description of the Related Art

An electrode structure is introduced in various electric/electronic devices such as a battery device, a lighting device, a display device, etc. In the lighting device and the display device, an electrode structure with improved transparency is employed for optical properties, an image quality, etc. Further, in a battery device such as a solar cell, an electrode structure with improved transparency is also employed to improve a light efficiency.

The electrode structure or a functional layer such as an organic light emitting layer, a photo-active layer, etc., may be oxidized when being exposed to a moisture penetrating from an outside of the battery device, and an operation in the functional layer may also be deteriorated.

In a recent thin-layered battery device, the oxidation and damages caused by the moisture penetration may easily occur.

Thus, research for improving a chemical stability of the device while improving the transparency of an electrode is needed.

### SUMMARY

According to an aspect of the present invention, there is provided a transparent electrode structure having improved optical, chemical and mechanical properties.

According to an aspect of the present invention, there is provided an electrical device such as a lighting device or a solar cell which includes the transparent electrode structure.

(1) A transparent electrode structure, comprising: a transparent substrate; a transparent electrode layer disposed on the transparent substrate, the transparent electrode layer including a multi-layered structure of a transparent oxide electrode layer and a metal layer; and a barrier structure disposed between the transparent substrate and the transparent electrode layer, the barrier structure including at least one barrier material of an aluminum oxide-zinc oxide composite (AlZO) material, silazane, siloxane or a silicon-containing inorganic material.

(2) The transparent electrode structure of the above (1), wherein the transparent electrode layer has an optical ratio defined by Equation 1 is 5 or less:

Optical ratio=an extinction coefficient of the metal layer/(|a refractive index of the transparent oxide electrode layer−a refractive index of the metal layer|) [Equation 1].

(3) The transparent electrode structure of the above (2), wherein the transparent oxide electrode layer comprises a first transparent oxide electrode layer and a second transparent oxide electrode layer, and the metal layer is disposed between the first transparent oxide electrode layer and the second transparent oxide electrode layer.

(4) The transparent electrode structure of the above (3), wherein the optical ratio between the metal layer and the first transparent oxide electrode layer is 5 or less, and the optical ratio between the metal layer and the second transparent oxide electrode layer is 5 or less.

(5) The transparent electrode structure of the above (3), wherein each thickness of the first transparent oxide electrode layer and the second transparent oxide electrode layer is from 200 to 800 Å, and a thickness of the metal layer is from 50 to 500 Å.

(6) The transparent electrode structure of the above (1), wherein a refractive index of the transparent oxide electrode layer is from 1.7 to 2.2, and the metal layer includes a silver (Ag) alloy.

(7) The transparent electrode structure of the above (1), wherein the barrier structure comprises a barrier layer including the barrier material and an organic layer stacked on the barrier layer.

(8) The transparent electrode structure of the above (7), wherein the barrier layer includes the ALZO material or silazane.

(9) The transparent electrode structure of the above (7), wherein the barrier structure comprises a plurality of the barrier layers and a plurality of the organic layers which are alternately stacked.

(10) The transparent electrode structure of the above (1), wherein the barrier structure has a multi-layered structure comprising a first barrier layer and a second barrier layer, each of which includes the barrier material.

(11) The transparent electrode structure of the above (10), wherein the first barrier layer includes the silicon-containing inorganic material and the second barrier layer includes silazane.

(12) The transparent electrode structure of the above (11), wherein the barrier structure includes a pair of the first barrier layers facing each other with the second barrier layer interposed therebetween.

(13) The transparent electrode structure of the above (11), wherein the barrier structure includes a plurality of the first barrier layers and a plurality of the second barrier layers which are alternately stacked.

(14) The transparent electrode structure of the above (1), wherein a surface roughness of the barrier structure is 5 nm or less.

(15) The transparent electrode structure of the above (14), wherein the surface roughness of the barrier structure is 0.2 to 3 nm.

(16) The transparent electrode structure of the above (1), further including a lower insulating layer disposed between the transparent substrate and the barrier structure.

(17) The transparent electrode structure of the above (16), wherein the lower insulating layer includes a transfer intermediate layer including an organic polymer material.

(18) A lighting device, comprising: the transparent electrode structure according to embodiments as described above; an organic light emitting layer disposed on the transparent electrode structure; and an upper electrode disposed on the organic light emitting layer.

(19) A solar cell, comprising: the transparent electrode structure according to embodiments as described above; a photo-active layer disposed on the transparent electrode structure; and an upper electrode disposed on the photo-active layer.

A transparent electrode structure according to embodiments of the present invention may include a transparent electrode layer including a transparent oxide electrode layer and a metal layer. Accordingly, a low resistance and a high transmittance may be obtained together.

Additionally, an extinction coefficient and a refractive index between the metal layer and the transparent oxide electrode layer may be adjusted, so that a light reflection generated from the metal layer may be reduced, and a transmittance may be improved.

In some embodiments, the transparent electrode layer may include a triple-layered structure including a first transparent oxide electrode layer-a metal layer-a second transparent oxide electrode layer to further improve the transmittance and a corrosion resistance of the transparent electrode layer.

In some embodiments, a barrier structure may be inserted between the transparent electrode layer and a substrate to prevent an oxidation of the transparent electrode layer and to further improve a chemical stability.

Further, a surface roughness of the barrier structure may be adjusted to 5 nm or less, so that a mechanical stability of the transparent electrode structure may be further improved.

A lighting device and a battery device having improved optical, chemical and mechanical stability may be fabricated utilizing the transparent electrode structure.

### BRIEF DESCRIPTION OF THE DRAWINGS

FIG. 1 is a schematic cross-sectional view illustrating a transparent electrode structure in accordance with exemplary embodiments.

FIGS. 2 to 7 are schematic cross-sectional views illustrating barrier structures in accordance with some exemplary embodiments.

FIG. 8 is a schematic cross-sectional view illustrating an electrical device to which a transparent electrode structure in accordance with exemplary embodiments is applied.

FIG. 9 is a schematic cross-sectional view illustrating an electrical device to which a transparent electrode structure in accordance with exemplary embodiments is applied.

### DETAILED DESCRIPTION OF THE EMBODIMENTS

According to embodiments of the present invention, there is provided a transparent electrode structure including a multi-layered structure of a transparent oxide electrode layer and a metal layer to have improved optical property and stability. Further, there is also provided an electrical device such as a lighting device or a battery device to which the transparent electrode structure is employed.

Hereinafter, the present invention will be described in detail with reference to the accompanying drawings. However, those skilled in the art will appreciate that such embodiments described with reference to the accompanying drawings are provided to further understand the spirit of the present invention and do not limit subject matters to be protected as disclosed in the detailed description and appended claims.

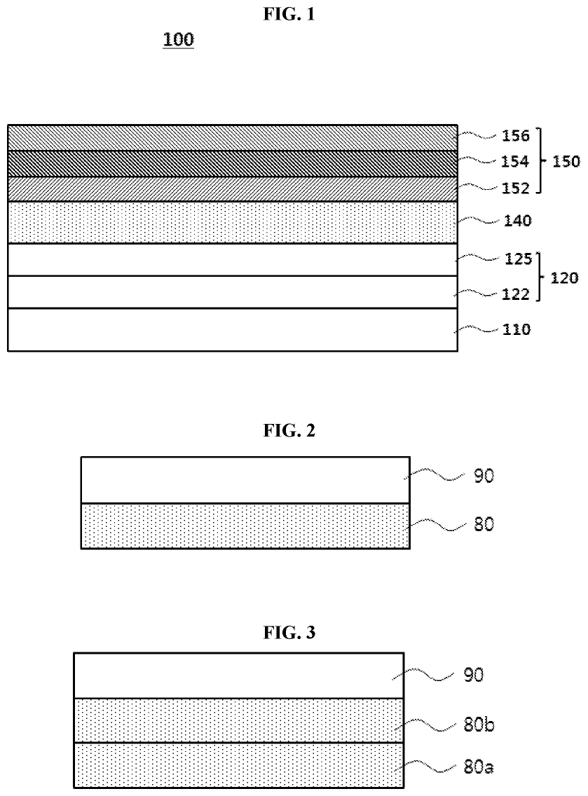

FIG. 1 is a schematic cross-sectional view illustrating a transparent electrode structure in accordance with exemplary embodiments.

Referring to FIG. 1, a transparent electrode structure 100 may include a barrier structure 140 and a transparent electrode layer 150 stacked on a transparent substrate 110. In some embodiments, a lower insulating layer 120 may be further included between the barrier structure 140 and the transparent substrate 110.

The transparent substrate 110 may include glass having a high light transmittance, a transparent resin material, or the like. Examples of the transparent resin material include cyclic olefin polymer (COP), polyethylene terephthalate (PET), polyacrylate (PAR), polyetherimide (PEI), polyethylene naphthalate (PEN), polyphenylene sulfide (PPS), polyallylate, polyimide (PI), cellulose acetate propionate (CAP), polyethersulfone (PES), cellulose triacetate (TAC), polycarbonate (PC), cyclic olefin copolymer (COC), polymethyl methacrylate (PMMA), etc.

In some embodiments, the lower insulating layer 120 may be disposed on the transparent substrate 110. The lower insulating layer 120 may serve as an intermediate layer for transferring the transparent electrode layer 150 to the transparent substrate 110 while protecting the transparent electrode layer 150.

For example, the lower insulating layer 120 may include an intermediate layer 122 and a protective layer 125 sequentially stacked on a top upper surface of the transparent substrate 110.

The intermediate layer 122 may include a film of an organic polymer. Non-limiting examples of the organic polymer may include a polyimide-based polymer, a polyvinyl alcohol-based polymer, a polyamic acid-based polymer, and a polyamide-based polymer, a polyethylene-based polymer, a polystyrene-based polymer, a polynorbornene-based polymer, a phenylmaleimide copolymer-based polymer, a polyazobenzene-based polymer, a polyphenylene phthalamide-based polymer, a polyester-based polymer, a polymethyl methacrylate-based polymer, a polyarylate-based polymer, a cinnamate-based polymer, a coumarin-based polymer, a phthalimidine-based polymer, a chalcone-based polymer, an aromatic acetylene-based polymer, or the like. These may be used alone or in a combination of 2 or more therefrom.

The protective layer 125 may be formed on the intermediate layer 122. The protective layer 125 may include, e.g., an organic material such as an acrylic polymer. In an embodiment, the protective layer 125 may be omitted.

For example, the lower insulating layer 120, the barrier structure 140 and the transparent electrode layer 150 may be formed on a carrier substrate (not illustrated), and then the carrier substrate may be detached from the lower insulating layer 120. Thereafter, the transparent substrate 110 may be adhered to a detachment surface of the intermediate layer 120 through an adhesive layer.

As described above, the transparent electrode structure 100 may be obtained through a transfer process combining the transparent substrate 110 after the formation of the transparent electrode layer 150. Thus, the transparent substrate 110 may be prevented from being damaged by a high-temperature deposition process such as a sputtering process performed when forming the barrier structure 140 or the transparent electrode layer 150, and the thinner transparent substrate 110 may be used to easily obtain a thin-layered structure of the transparent electrode structure 100 and an electric device.

The barrier structure 140 may be disposed on the lower insulating layer 120. The barrier structure 140 may include a barrier material having improved a moisture shielding property.

In exemplary embodiments, the barrier material may include an aluminum oxide (e.g., Al₂O₃)-zinc oxide (e.g., ZnO) composite (AlZO) material, silazne, siloxane and/or a silicon-containing inorganic materials.

In the present application, “silazane” is used as a term encompassing a compound or a polymer including a structure of “—Si—N—Si—”. “Siloxane” is used as a term encompassing a compound or a polymer including a structure of “—Si—O—Si—”.

Examples of the silicon-containing inorganic material include silicon oxide, silicon nitride and/or silicon oxynitride. These may be used alone or in a combination of at least two therefrom. Preferably, at least two of silicon oxide, silicon nitride and silicon oxynitride may be used together, and more preferably, silicon oxide, silicon nitride and silicon oxynitride may be used together.

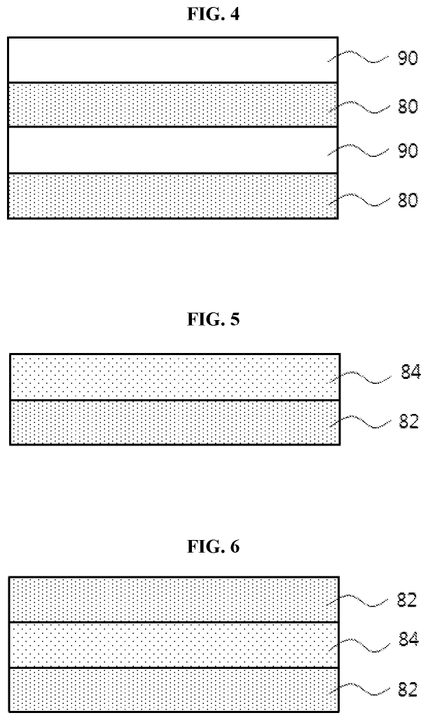

The barrier structure 140 may have a single-layered or multi-layered structure including the above-described barrier material. Examples of the barrier structure 140 having the multi-layered structure will be described later with reference to FIGS. 2 to 7.

The transparent electrode layer 150 may be disposed on the barrier structure 140. The transparent electrode layer 150 may include a multi-layered structure including a transparent oxide electrode layer and a metal layer.

In exemplary embodiments, the transparent electrode layer 150 may include a stacked structure of a first transparent oxide electrode layer 152, a metal layer 154 and a second transparent oxide electrode layer 156 sequentially stacked from a top surface of the barrier structure 140.

The first transparent oxide electrode layer 152 and the second transparent oxide electrode layer 156 may include a transparent conductive oxide such as indium tin oxide (ITO), indium zinc oxide (IZO), zinc oxide (ZnO), indium zinc tin oxide (IZTO), aluminum doped zinc oxide. (AlZO), gallium-doped zinc oxide (GZO), zinc tin oxide (ZTO), indium gallium oxide (IGO), tin oxide (SnO₂), or the like.

In some embodiments, the first transparent oxide electrode layer 152 and the second transparent oxide electrode layer 156 may include ITO or IZO.

The metal layer 154 may include silver (Ag), gold (Au), copper (Cu), aluminum (Al), platinum (Pt), palladium (Pd), chromium (Cr), titanium (Ti), tungsten (W), Niobium (Nb), tantalum (Ta), vanadium (V), iron (Fe), manganese (Mn), cobalt (Co), nickel (Ni), zinc (Zn), molybdenum (Mo), calcium (Ca) or an alloy thereof (e.g., silver-palladium-copper (APC)). These may be used alone or in combination of two or more.

In exemplary embodiments, the metal layer 154 may include a material satisfying a range of an optical ratio to be described later, and may preferably include a silver alloy such as APC.

As described above, the metal layer 154 may be included in the transparent electrode layer 150 to reduce a resistance to improve an activation rate or a reaction rate of, e.g., a lighting device and a battery device. Additionally, an overall flexibility of the transparent electrode layer 150 may be enhanced by the metal layer 154, so that damages to the electrode may be prevented even when repeated folding and bending are applied.

The transparent oxide electrode layers 152 and 156 having relatively improved chemical resistance may be disposed on upper and lower surfaces of the metal layer 154, so that oxidation or corrosion due to external moisture and air penetration of the metal layer 154 may be prevented. Further, a transmittance of the transparent electrode layer 150 may be improved by the transparent oxide electrode layers 152 and 156, thereby improving an optical efficiency of the electric device.

In exemplary embodiments, the refractive indices of the transparent oxide electrode layers 152 and 156 may each be adjusted in a range from about 1.7 to 2.2 to reduce a reflection by a refractive index matching with the metal layer 154. For example, in the case of ITO, the refractive index may be controlled through a sputtering process using a target in which ae weight ratio of indium oxide (In₂O₃) and tin oxide (SnO₂) is controlled.

In exemplary embodiments, a ratio of an extinction coefficient of the metal layer relative to a refractive index difference between the metal layer and the transparent oxide electrode layer (hereinafter, referred to as an optical ratio) may be 5 or less (expressed by Equation 1 below). For example, the optical ratio may range from about 1 to 5.

Optical ratio=extinction coefficient of metal layer/(|refractive index of the transparent oxide electrode layer−refractive index of the metal layer|) [Equation 1]

When Equation 1 is satisfied, a transmittance may be remarkably increased while reducing a reflectance of the transparent electrode layer 150. In a preferable embodiment, the optical ratio may be about 3 or less (e.g., 1 to 3).

The extinction coefficient is an index indicating an intensity of light per unit path in the metal layer 154 and may be obtained by Equations 1 and 2 below.

I=I₀e^{(-αT)} [Formula 1]

In Equation 1, a denotes an absorption coefficient, T denotes a thickness, I₀ denotes an intensity of light before transmission, and I denotes an intensity of light after transmission.

α=4πk/λ₀ [Equation 2]

In Equation 2, α denotes an absorption coefficient, k denotes an extinction coefficient, and λ₀ denotes a wavelength of light.

When the optical ratio range of Equation 1 is satisfied, an excessive extinction of transmitted light in the transparent electrode layer 150 may be prevented, and reduction of luminous and light collection efficiency due to a light reflection may be effectively suppressed.

In exemplary embodiments, the optical ratio between the metal layer 154 and the first transparent oxide electrode layer 152 may be 5 or less, and the optical ratio between the metal layer 154 and the second transparent oxide electrode layer 156 may be 5 or less.

The metal layer 154 may be formed to have a thickness smaller than a thickness of each of the first and second transparent oxide electrode layers 152 and 156 to improve transmittance.

In some embodiments, each thickness of the first and second transparent oxide electrode layers 152 and 156 may be from about 200 to 800 Å, preferably from about 300 to 500 Å. In some embodiments, the thickness of the metal layer 154 may be from about 50 to 500 Å, preferably from about 70 to 200 Å.

In a combination of the value of the Equation 1 above and the thickness range, the effect of suppressing reflectance and improving transmittance may be more effectively implemented.

In an embodiment, a protective film such as an encapsulation film or a release film may be formed on the transparent electrode layer 150.

As described above, the transparent oxide electrode layers 152 and 156 may be included in the transparent electrode layer 150 together with the metal layer 154, so that a low resistance property of the metal layer 154 may be utilized while preventing the damages by the moisture and air.

Additionally, the barrier structure 140 may be disposed on the transparent electrode layer 150, so that mechanical and chemical stability of the transparent electrode layer 150 may be more effectively improved by blocking the external moisture and the external air penetrating into the transparent electrode layer 150.

In some embodiments, a moisture permeability of the barrier structure 140 may be in a range from 10⁻⁶ to 10⁻¹ g/m²·24 hr at 40° C. and 90% relative humidity.

In some embodiments, a surface roughness of the barrier structure 140 may be about 5 nm or less. Preferably, the surface roughness of the barrier structure 140 may be about 4 nm or less, and more preferably, about 3 nm or less.

When satisfying the surface roughness, a difference of electrode resistance due to a rough surface of the transparent electrode structure 100 may be effectively prevented. Accordingly, stains or dark spots formed by the difference in electrode resistance may be effectively prevented in the transparent electrode structure 100.

For example, as the surface roughness of the barrier structure 140 decreases, the surface of the barrier structure 140 may be densely formed, so that the moisture permeability of the barrier structure 140 may decrease. Accordingly, the external moisture and the external air penetrating into the transparent electrode layer 150 may be blocked so that mechanical and chemical stability of the transparent electrode layer 150 may be more effectively improved.

In some embodiments, the surface roughness of the barrier structure 140 may be, e.g., 0.2 nm or more, and more preferably 0.3 nm or more. In the above range, an adhesive force between the barrier structure 140 and the transparent electrode layer 150 may be increased, so that mechanical properties of the transparent electrode structure 100 may be improved.

In some embodiments, the barrier structure 140 may further include a barrier layer including an AlZO material, siloxane, silazane or a silicon-containing inorganic material and an organic layer stacked on the barrier layer. More preferably, the barrier layer may include the AlZO material, siloxane or the silicon-containing inorganic material.

For example, when the barrier layer includes an AlZO material, siloxane or the silicon-containing inorganic material, a moisture resistance of the transparent electrode structure may be further improved.

For example, if the barrier layer includes an AlZO material, the surface roughness of the barrier structure 140 may be from about 0.1 to 1.5 nm. If the barrier layer includes siloxane, the surface roughness of the barrier structure 140 may be from about 0.2 to 4.0 nm. If the barrier layer includes the silicon-containing inorganic material, the surface roughness of the barrier structure 140 may be from about 0.2 to 5.5 nm.

FIGS. 2 to 7 are schematic cross-sectional views illustrating barrier structures in accordance with some exemplary embodiments.

As described above, the barrier structure 140 illustrated in FIG. 1 may include a barrier structure having a multi-layered structure including the above-described barrier material.

Referring to FIG. 2, the barrier structure may include a barrier layer 80 including the above-described barrier material and an organic layer 90 stacked on the barrier layer 80.

The organic layer 90 may include, e.g., an acrylic resin or a siloxane-based resin. The organic layer 90 may be formed on the barrier layer 80, so that a process damage such as an etching damage and a thermal damage of the barrier material may be prevented or reduced. In this case, the barrier layer 80 may include the AlZO material, siloxane or the silicon-containing inorganic material.

Additionally, if the barrier layer 80 includes the AlZO material, a parasitic current that may be generated in the barrier layer 80 may be blocked by the organic layer 90. The organic layer 90 may be disposed between the transparent electrode layer 150 and the barrier layer 80.

Referring to FIG. 3, the barrier structure may include a multi-layered barrier layer stack. For example, the organic layer 90 may be formed on the barrier layer stack including a lower barrier layer 80a and an upper barrier layer 80b.

In an embodiment, the lower barrier layer 80a and the upper barrier layer 80b may each independently include the AlZO material or silazane.

Referring to FIG. 4, the barrier layer 80 and the organic layer 90 may be alternately and repeatedly stacked. In this case, a plurality of the barrier layers 80 may be spaced apart from each other, so that moisture shielding property may be further improved. As described above, each of the barrier layers 80 may include the AlZO material, siloxane, the silicon-containing inorganic material or silazane.

Referring to FIG. 5, the barrier structure may have a multi-layered structure (e.g., a double-layered structure) including a first barrier layer 82 and a second barrier layer 84.

In an embodiment, the first barrier layer 82 and the second barrier layer 84 may include the silicon-containing inorganic material.

In an embodiment, the first barrier layer 82 may include the silicon-containing inorganic material, and the second barrier layer 84 may include silazane.

Referring to FIG. 6, the second barrier layer 84 may be sandwiched between the first barrier layers 82. For example, the first barrier layers 82 may be formed on top and bottom surfaces of the second barrier layer 84.

In an embodiment, the first barrier layers 82 including the silicon-containing inorganic material may cover top and bottom surfaces of the silazane-containing second barrier layer 84, so that moisture may be more effectively prevented from being diffused into the transparent electrode layer 150.

Referring to FIG. 7, the first barrier layer 82 and the second barrier layer 84 may be alternately and repeatedly laminated to form a structure having four or more layers.

In an embodiment, as illustrated in FIG. 7, the first barrier layers 82 including the silicon-containing inorganic material and the second barrier layers 84 including silazane may be alternately stacked to form a quad-layered structure serving as the barrier structure.

Each of the barrier layers illustrated in FIGS. 2 to 7 may have an appropriate thickness according to a material included therein. For example, if the barrier layer includes the AlZO material, the barrier layer may have a thickness from about 10 nm to about 1 μm. If the barrier layer includes silazane, the barrier layer may have a thickness from about 100 nm to 2 μm. If the barrier layer includes the silicon-containing inorganic material, the barrier layer may have a thickness from about 10 nm to about 1 μm.

A moisture permeability of the above-described barrier structure may be in a range from 10⁻⁶ to 10⁻¹ g/m²·24 hr under a condition of 40° C. and 90% relative humidity.

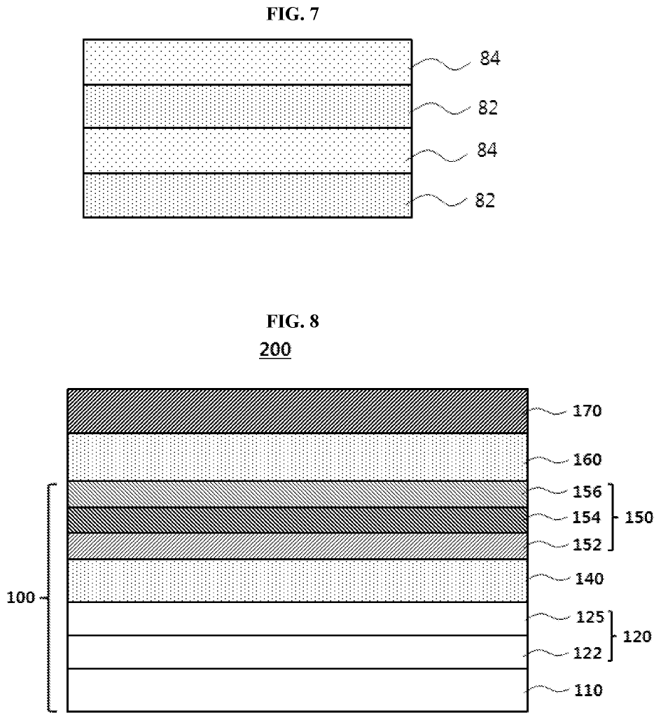

FIG. 8 is a schematic cross-sectional view illustrating an electrical device to which a transparent electrode structure in accordance with exemplary embodiments is applied. For example, FIG. 8 illustrates a lighting device including the transparent electrode structure according to the above-described exemplary embodiments.

Referring to FIG. 8, a lighting device 200 may include a light emitting layer 160 and an upper electrode 170 sequentially stacked on the above-described transparent electrode structure 100.

The light emitting layer 160 may include, e.g., an organic light emitting material widely known in the related art. In this case, the lighting device 200 may be provided as an OLED lighting device.

In an embodiment, a hole transport layer (HTL) may be further included between the transparent electrode layer 150 and the light emitting layer 160. In an embodiment, an electron transport layer (ETL) may be further included between the light emitting layer 160 and the upper electrode 170.

For example, the transparent electrode layer 150 may serve as an anode of the lighting device 200, and the lighting device 200 may be a bottom-emission type in which light is emitted through the transparent substrate 110. In this case, the upper electrode 170 may serve as a cathode and a reflective electrode of the lighting device 200.

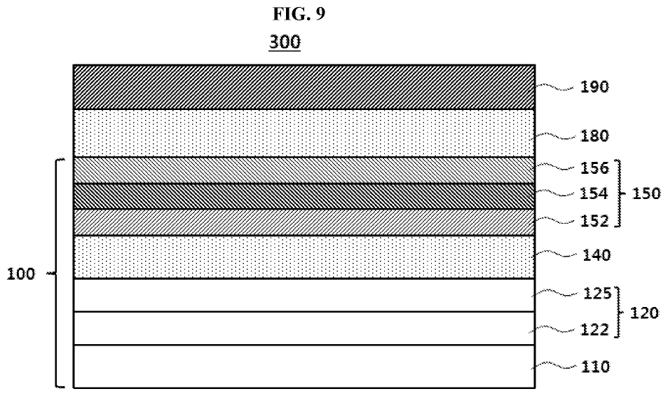

FIG. 9 is a schematic cross-sectional view illustrating an electrical device to which a transparent electrode structure in accordance with exemplary embodiments is applied. For example, FIG. 9 illustrates a battery device such as a solar cell including the transparent electrode structure according to the above-described exemplary embodiments.

Referring to FIG. 9, a battery device 300 may include a photo-active layer 180 and an upper electrode 190 sequentially stacked on the transparent electrode structure 100 as described above. The photo-active layer 180 may include, e.g., a light absorption layer including an organic polymer widely known in the related art included in a solar cell.

In an embodiment, a hole transport layer may be further included between the transparent electrode layer 150 and the photo-active layer 180.

In an embodiment, the transparent electrode layer 150 may serve as an anode of the battery device 300, and the upper electrode 190 may serve as a cathode of the battery device 300.

Hereinafter, preferred embodiments are proposed to more concretely describe the present invention. However, the following examples are only given for illustrating the present invention and those skilled in the related art will obviously understand that various alterations and modifications are possible within the scope and spirit of the present invention. Such alterations and modifications are duly included in the appended claims.

### Example 1

A lower insulating layer including a polyimide-based polymer, a barrier structure including an AlZO material and an electrode layer having a triple-layered structure (an ITO layer, a Cu layer and an ITO layer) were sequentially stacked on a transparent glass (a carrier substrate).

Specifically, a thickness of the barrier structure was 2 μm, and a thickness of the electrode layer was 84 nm.

The barrier structure was formed by depositing a barrier layer on the lower insulating layer using an AlZO target in a sputtering process chamber. Thereafter, an organic layer was formed on the barrier structure.

A surface roughness of the barrier structure measured using AFM (PSIA XE-100) under conditions of a scan size of 1.5 μm square and a scan rate of 1.0 Hz was 0.5 nm.

The glass substrate was detached from the stack structure of the lower insulating layer, the barrier structure and the transparent electrode layer, and then polyethylene terephthalate (PET) was attached to a bottom of the lower insulating layer.

### Examples 2 to 6

Transparent electrode structures were manufactured by the same method as that in Example 1, except that a type of the barrier material included in the barrier structure was changed and a surface roughness was changed by controlling an amount of oxygen and power in the sputtering process as shown in Table 1 below

### Examples 7 to 11

A transparent electrode structure was manufactured by the same method as that in Example 1, except that the barrier material included in the barrier structure was changed to the inorganic silicon-containing material, and the barrier structure was formed by a CVD method.

### Example 12

A transparent electrode structure was manufactured by the same method as that in Example 1, except that the barrier material included in the barrier structure was changed to silazane, and the barrier structure was formed by a spin coating method.

### Comparative Example

A transparent electrode structure was prepared by the same method as that in Example 1, except that the formation of the barrier structure on the carrier substrate was omitted.

TABLE 1

| | Barrier Material | Surface Roughness (nm) |
|---|---|---|
| Example 1 | AlZO material | 0.5 |
| Example 2 | AlZO/siloxane composite | 0.7 |
| Example 3 | AlZO material | 0.4 |
| Example 4 | AlZO material | 0.3 |
| Example 5 | AlZO material | 0.2 |
| Example 6 | AlZO material | 0.19 |
| Example 7 | silicon-containing inorganic | 3 |
| | material | |
| Example 8 | silicon-containing inorganic | 3.1 |
| | material | |
| Example 9 | silicon-containing inorganic | 4 |
| | material | |
| Example 10 | silicon-containing inorganic | 5 |
| | material | |
| Example 11 | silicon-containing inorganic | 5.1 |
| | material | |
| Example 12 | silicon-containing inorganic | 0.2 |
| | material | |
| Example 13 | silazane | 3.5 |
| Comparative | — | — |
| Example | | |

### Experimental Example

<Evaluation on Generation of Initial Dark Spots>

OLED lighting devices including the transparent electrode structures according to Examples 1 to 13 and Comparative Example were prepared.

A voltage was applied to the manufactured OLED lighting device to generate a light. While observing from an upper side of the OLED lighting device, it was visually determined whether dark spots existed in the generated light over time at a temperature of 60° C. and a humidity of 90%.

The case in which no initial dark spot was detected formed is denoted as ⊚, the case in which one initial dark spot was detected is denoted as ◯, the case in which two initial dark spots were formed is denoted as Δ, and the case in which three or more initial dark spots were formed is denoted as X. The measurement results are shown in Table 2.

<Measurement of Moisture Permeability>

Water vapor permeation rate of the transparent electrode structures according to Examples 1 to 13 and Comparative Example were measured according to JIS-K7129 standard (temperature 40° C., humidity 90% RH) using MOCON Aquatran 2.

The measurement results are shown in Table 2.

TABLE 2

| | Generation of initial | Water permeability |
|---|---|---|
| | dark spot | (g/m²/day) |
| Example 1 | ⊚ | 0.00005 |
| Example 2 | ⊚ | 0.0007 |
| Example 3 | ⊚ | 0.00007 |
| Example 4 | ⊚ | 0.00007 |
| Example 5 | ⊚ | 0.00005 |
| Example 6 | ⊚ | 0.00005 |
| Example 7 | ⊚ | 0.003 |
| Example 8 | ◯ | 0.0041 |
| Example 9 | ◯ | 0.0054 |
| Example 10 | ◯ | 0.0057 |
| Example 11 | Δ | 0.0062 |
| Example 12 | ◯ | 0.00005 or less |
| Example 13 | ◯ | 0.75 |
| Comparative | X | 18 |
| Example | | |

Referring to Table 2, the transparent electrode structure of Comparative Example that did not include the barrier structure had a high water vapor permeating rate, and the dark spots were present on a surface of the transparent electrode structure. As a result, when a current was applied through the transparent electrode structure of Comparative Example, optical properties of the transparent electrode structure are gradually deteriorated due to the dark spots.

In Examples 1 to 10 and Examples 12 and 13 where the surface roughness values of the barrier structures were 5 nm or less, the generation of the initial dark spot was suppressed when compared to the case of Example 11, and further improved moisture permeability results were provided.

Further, in Example 6 having the surface roughness of less than 0.2 nm, the generation of the initial dark spot was suppressed and provided a low moisture permeability, but an adhesion between the barrier structure and the transparent substrate was slightly decreased.

What is claimed is:

1. A transparent electrode structure, comprising:
a transparent substrate;
a transparent electrode layer disposed on the transparent substrate, the transparent electrode layer including a multi-layered structure of a transparent oxide electrode layer and a metal layer; and
a barrier structure disposed between the transparent substrate and the transparent electrode layer, the barrier structure including at least one barrier material of an aluminum oxide-zinc oxide composite (AlZO) material, silazane, siloxane or a silicon-containing inorganic material.

2. The transparent electrode structure of claim 1, wherein the transparent electrode layer has an optical ratio defined by Equation 1 is 5 or less:
Optical ratio=an extinction coefficient of the metal layer/(|a refractive index of the transparent oxide electrode layer−a refractive index of the metal layer|) [Equation 1].

3. The transparent electrode structure of claim 2, wherein the transparent oxide electrode layer comprises a first transparent oxide electrode layer and a second transparent oxide electrode layer, and
the metal layer is disposed between the first transparent oxide electrode layer and the second transparent oxide electrode layer.

4. The transparent electrode structure of claim 3, wherein the optical ratio between the metal layer and the first transparent oxide electrode layer is 5 or less, and the optical ratio between the metal layer and the second transparent oxide electrode layer is 5 or less.

5. The transparent electrode structure of claim 3, wherein each thickness of the first transparent oxide electrode layer and the second transparent oxide electrode layer is from 200 to 800 Å, and a thickness of the metal layer is from 50 to 500 Å.

6. The transparent electrode structure of claim 1, wherein a refractive index of the transparent oxide electrode layer is from 1.7 to 2.2, and the metal layer includes a silver (Ag) alloy.

7. The transparent electrode structure of claim 1, wherein the barrier structure comprises a barrier layer including the barrier material and an organic layer stacked on the barrier layer.

8. The transparent electrode structure of claim 7, wherein the barrier layer includes the AlZO material or silazane.

9. The transparent electrode structure of claim 7, wherein the barrier structure comprises a plurality of the barrier layers and a plurality of the organic layers which are alternately stacked.

10. The transparent electrode structure of claim 1, wherein the barrier structure has a multi-layered structure comprising a first barrier layer and a second barrier layer, each of which includes the barrier material.

11. The transparent electrode structure of claim 10, wherein the first barrier layer includes the silicon-containing inorganic material and the second barrier layer includes silazane.

12. The transparent electrode structure of claim 11, wherein the barrier structure includes a pair of the first barrier layers facing each other with the second barrier layer interposed therebetween.

13. The transparent electrode structure of claim 11, wherein the barrier structure comprises a plurality of the first barrier layers and a plurality of the second barrier layers which are alternately stacked.

14. The transparent electrode structure of claim 1, wherein a surface roughness of the barrier structure is 5 nm or less.

15. The transparent electrode structure of claim 14, wherein the surface roughness of the barrier structure is 0.2 to 3 nm.

16. The transparent electrode structure of claim 1, further comprising a lower insulating layer disposed between the transparent substrate and the barrier structure.

17. The transparent electrode structure of claim 16, wherein the lower insulating layer includes a transfer intermediate layer including an organic polymer material.

18. A lighting device, comprising:
the transparent electrode structure of claim 1;
an organic light emitting layer disposed on the transparent electrode structure; and
an upper electrode disposed on the organic light emitting layer.

19. A solar cell, comprising:
the transparent electrode structure of claim 1;
a photo-active layer disposed on the transparent electrode structure; and
an upper electrode disposed on the photo-active layer.
